(19) United States
(12) Patent Application Publication
(10) Pub. No.: US 2025/0118536 A1
(43) Pub. Date: Apr. 10, 2025

(54) MICROWAVE HIGH-DENSITY PLASMA FOR SELECTIVE ETCH

(71) Applicant: Applied Materials, Inc., Santa Clara, CA (US)

(72) Inventors: Yi-Hsuan Hsiao, San Jose, CA (US); Dongqing Yang, Pleasanton, CA (US); Kelvin Chan, San Ramon, CA (US); Philip A. Kraus, San Jose, CA (US); Thai Cheng Chua, Cupertino, CA (US); Ping-Hwa Hsieh, Mipitas, CA (US); Nitin K. Ingle, San Jose, CA (US)

(73) Assignee: Applied Materials, Inc., Santa Clara, CA (US)

(21) Appl. No.: 18/484,379

(22) Filed: Oct. 10, 2023

(51) Int. Cl. H01J 37/32; H01L 21/311

(52) U.S. Cl. CPC H01J 37/32201; H01J 37/32357; H01J 37/32449; H01L 21/31116; H01J 2237/3343

(57) ABSTRACT

Semiconductor processing systems and methods for increased etch selectivity and rate are provided. Methods include etching a target material of a semiconductor substrate by flowing one or more plasma precursors through a microwave applicator into a remote plasma region of a semiconductor processing chamber. Generating a remote plasma within the remote plasma region at a microwave frequency, where the generated remote plasma comprises a density of greater than 1×10¹⁰ per cm³, an ion energy of less than or about 50 eV, or a combination thereof. Flowing the plasma effluents into a processing region of the semiconductor processing chamber. The microwave applicator includes a resonator body and a plate, where the resonator body is formed from or coated with a first dielectric material and the plate is formed from or coated with a second dielectric material.

### TECHNICAL FIELD

The present technology relates to components, apparatuses, and processing methods for semiconductor manufacturing. More specifically, the present technology relates to processing chamber distribution components and other semiconductor processing equipment.

### BACKGROUND OF THE INVENTION

Integrated circuits are made possible by processes which produce intricately patterned material layers on substrate surfaces. Producing patterned material on a substrate requires controlled methods for forming and removing material. Chamber components often deliver processing gases to a substrate for depositing films or removing materials. To promote symmetry and uniformity, some chambers include remote plasma sources in order to generate higher power plasmas without damaging substrates. However, this may limit the ability to tune recipes for on-wafer adjustments.

Thus, there is a need for improved systems and methods that can be used to produce high quality devices and structures. These and other needs are addressed by the present technology.

### BRIEF SUMMARY OF THE INVENTION

The present technology is generally directed to methods for etching a target material of a semiconductor substrate. Methods include flowing one or more plasma precursors through a microwave applicator into a remote plasma region of a semiconductor processing chamber. Methods include generating a remote plasma within the remote plasma region at a microwave frequency, forming plasma effluents, where the generated remote plasma exhibits a density of greater than 1×10¹⁰ per cm³, an ion energy of less than or about 50 eV, or a combination thereof. Methods include flowing the plasma effluents into a processing region of the semiconductor processing chamber, where the microwave applicator includes a resonator body, and a plate. Methods include where the resonator body is formed from or coated with a first dielectric material and the plate is formed from or coated with a second dielectric material.

In embodiments, the plasma effluents exhibit an etch selectivity between two or more of silicon germanium (SiGe), an oxide material, a nitride material, and a polysilicon material, of greater than or about 1:1. In more embodiments, the etch selectivity is greater than or about 10:1. Furthermore in embodiments, the etch selectivity is exhibited between SiGe and the oxide material, SiGe and the nitride material, or between SiGe and both the oxide material and the nitride material. In yet further embodiments, the oxide material includes silicon oxide, the nitride material includes silicon nitride, or a combination thereof. Additionally or alternatively, in embodiments, the first dielectric material includes Al, electroless nickel plated aluminum, AlO, MgF₂, YF₃, NiF₂, LiF, BaF₂, CaF₂ or a combination thereof. Embodiments include where the second dielectric material includes quartz, alumina, sapphire, MgF₂, yttrium aluminum garnet, Y₂O3, MgO, calcium fluoride, barium fluoride, lithium fluoride, fused silica, borosilicate glass, or a combination thereof. In embodiments, the one or more plasma precursors include a hydrogen-containing precursor and/or a halogen-containing precursor, alone or in combination with an inert carrier gas. Moreover, in embodiments, the one or more plasma precursors include hydrogen (H₂) and a fluorine-containing material, where a ratio of hydrogen to the fluorine-containing material is from about 0:1 to about 100:1. In further embodiments, the ratio of hydrogen to the fluorine-containing material is greater than or about 3:1. In more embodiments, a plasma source power is about 25 watts to about 300 watts. In embodiments, the plasma source power is less than or about 50 watts. Furthermore, in embodiments, methods include flowing hydrogen into the remote plasma region or the processing region at a rate of less than or about 1500 sccm. In embodiments, the etching is conducted at a pressure of about 1 torr to about 10 torr. Additionally or alternatively, the one or more plasma precursors include a nitrogen-containing precursor, where the nitrogen containing precursor is flowed into the processing region at a rate of about 25 sccm to about 150 sccm. In embodiments, the etch includes an oxide bulk removal, a native oxide preclean, an oxide/nitride removal, a nitride recess, a silicon germanium recess, or a combination thereof. Furthermore, in embodiments, the etching is conducted at a temperature of about 20° C. to about 125° C.

The present technology is also generally directed to methods of etching a target material of a semiconductor substrate. Methods include flowing one or more plasma precursors through a microwave applicator into a remote plasma region of a semiconductor processing chamber. Methods include generating a remote plasma within the remote plasma region at a microwave frequency, forming plasma effluents. Methods include flowing the plasma effluents into a processing region of the semiconductor processing chamber. Methods include where the microwave applicator contains a resonator body and a plate, where the resonator body is formed from or coated with a first dielectric material including Al, electroless nickel plated aluminum, AlO, MgF₂, YF₃, NiF₂, LiF, BaF₂, CaF₂ or a combination thereof. Methods include where the plate is formed from or coated with a second dielectric material including quartz, alumina, sapphire, MgF₂, yttrium aluminum garnet, Y₂O₃, MgO, calcium fluoride, barium fluoride, lithium fluoride, fused silica, borosilicate glass, or a combination thereof. In embodiments, the second dielectric material is sapphire.

The present technology is also generally directed to methods of etching a target material of a semiconductor substrate. Methods include flowing one or more plasma precursors through a microwave applicator into a remote plasma region of a semiconductor processing chamber. Methods include generating a remote plasma within the remote plasma region at a microwave frequency, forming plasma effluents. Methods include flowing the plasma effluents into a processing region of the semiconductor processing chamber. Methods include where the microwave applicator contains a resonator body and a plate, where the resonator body is formed from or coated with a first dielectric material and the plate is formed from or coated with a second dielectric material. Methods include where the plasma effluents exhibit an etch selectivity between the target material and a second material that includes silicon germanium (SiGe), an oxide material, a nitride material, and a polysilicon material, where the second material is different than the target material. Methods include where the target material includes the oxide material, and the first dielectric material includes an aluminum containing material, a ratio of hydrogen to a fluorine-containing precursor material is greater than or about 3:1, a plasma source power is less than or about 50 watts, or a combination thereof, and/or the target material includes silicon germanium, and the ratio of hydrogen to a fluorine-containing precursor material is less than or about 3:1, the plasma source power is less than or about 50 watts, or a combination thereof.

Such technology may provide numerous benefits over conventional systems and techniques. For example, embodiments of the present technology may provide substrate processing equipment and methods that may increase etch rates of a target material. In addition, systems and methods discussed herein may additionally or alternatively improve etch selectivity, alone or in conjunction with improved etch rates. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of an exemplary processing system according to embodiments of the present technology.

FIG. 2A is a perspective view of a microwave applicator with a resonator body over a plate according to embodiments of the present technology.

FIG. 2B is a perspective view of a remote plasma source that includes a microwave applicator according to embodiments of the present technology.

FIG. 3A is a cross-sectional illustration of a remote plasma source with a microwave applicator according to embodiments of the present technology.

FIG. 3B is a cross-sectional illustration of a remote plasma source with a microwave applicator according to embodiments of the present technology.

FIG. 4 is an illustration of a semiconductor processing tool with a remote plasma source that includes a microwave applicator according to embodiments of the present technology.

FIG. 5 shows an exemplary process flow according to embodiments of the present technology.

FIG. 6 illustrates a block diagram of an exemplary computer system that may be used in conjunction with embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION OF THE INVENTION

During plasma enhanced deposition processes, a remote plasma source (RPS) unit may be used to create and strike plasma. Generally, a remote plasma source includes an antechamber that is fluidically coupled to the main processing chamber. The plasma is struck in the antechamber and excited gas molecules flow out an exhaust that couples the antechamber to the main processing chamber. In this way, the plasma is moved away from the surface of the substrate that is being processed in the main processing chamber. Such systems allow for the creation of high powered plasma with reduced damage to the substrate.

However, existing remote plasma source units utilize energy sources that are not capable of producing high density plasma and have proven incapable of producing plasmas having densities of greater than 1×10¹⁰ cm³. High density plasma is advantageous, as an increase in dissociation of plasma ions may be achieved but may also increase damage to the system. Attempts have been made to improve these plasma sources, such as ferrite assisted plasma sources, however such systems have not achieved sufficiently high plasma density. Due at least in part to the low density and/or associated low frequency, inadequate dissociation is exhibited, leading to low etch rates and low selectivity.

Thus, efforts were made to utilize microwave remote plasma source units, as microwave units are capable of achieving high densities. However, existing microwave units have exhibited problems such as high ion energy, which results in substrate damage. Thus, efforts have been made to utilizing additional blocking plates and advanced mixing solutions. However, such efforts have failed to provide consistent high etch rates. In addition, existing microwave generated plasma exhibit relatively low selectivity.

The present technology overcomes these challenges by utilizing one or more chamber components formed from, or coated with, a material that increases an etch rate, an etch selectivity, or a combination thereof, to a target material. Surprisingly, the present technology has found that the use of such chamber components in conjunction with a microwave remote plasma source and one or more controlled process parameters, allows for carefully tailored etching of a target material to be achieved. Without wishing to be bound by theory, it is believed that by utilizing a microwave plasma source having a low ion energy and high density, an increase in ion dissociation is exhibited, where the ions are then able to combine with one or more component coatings to increase the etch selectivity and/or etch rate of a target material. Furthermore, due at least to the improvement in dissociation, the present technology has found that one or more of the coating, process gas(ses), process gas ratio, process temperature, process pressure, or a combination thereof, may be carefully selected to tailor the etch rate, the etch selectivity, or a combination thereof. In addition, it was found that the combination of a plasma formed utilizing a specific microwave frequency may provide a high-density plasma that also exhibits low ion energies. Thus, processes and systems according to the present technology may also surprisingly exhibit low occurrences of damage and improved wear of system components.

Although the remaining disclosure will routinely identify specific etching processes utilizing the disclosed technology, it will be readily understood that the systems and methods are equally applicable to deposition and cleaning processes as may occur in the described chambers. Accordingly, the technology should not be considered to be so limited as for use with such etching processes alone. The disclosure will discuss one possible system and chamber that can be used with the present technology to perform certain of the removal operations before describing component aspects and variations to this system according to embodiments of the present technology.

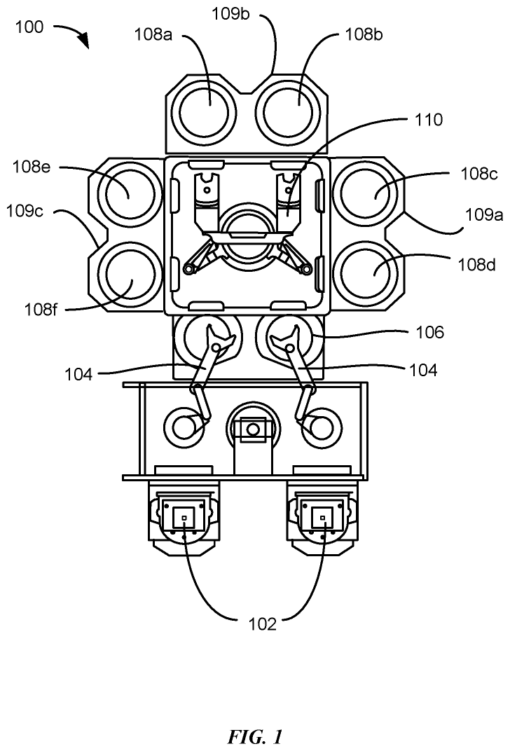

FIG. 1 shows a top plan view of one embodiment of a processing system 100 of deposition, etching, baking, and curing chambers according to embodiments. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including formation of stacks of semiconductor materials described herein in addition to plasma-enhanced chemical vapor deposition, atomic layer deposition, physical vapor deposition, etch, pre-clean, degas, orientation, and other substrate processes including, annealing, ashing, etc.

The substrate processing chambers 108a-f may include one or more system components for depositing, annealing, curing and/or etching a dielectric or other film on the substrate. In one configuration, two pairs of the processing chambers, e.g., 108c-d and 108e-f, may be used to deposit dielectric material on the substrate, and the third pair of processing chambers, e.g., 108a-b, may be used to etch the deposited dielectric. In another configuration, all three pairs of chambers, e.g., 108a-f, may be configured to deposit stacks of alternating dielectric films on the substrate. Any one or more of the processes described may be carried out in chambers separated from the fabrication system shown in different embodiments. It will be appreciated that additional configurations of deposition, etching, annealing, and curing chambers for dielectric films are contemplated by system 100.

As noted above, remote plasma sources may be necessary for some semiconductor processes in order to protect the substrate from the plasma. In some embodiments, the remote plasma source may be a microwave plasma source. More particularly, embodiments disclosed herein include solid state microwave power sources. The use of a solid state microwave power source provides a smaller form factor than traditional microwave plasma sources. For example, embodiments disclosed herein may not use large magnetrons, waveguides, and the like in order to transfer the microwave power from the power source to the applicator. Accordingly, embodiments allow for compact remote plasma sources. For instance, in embodiments, the microwave plasma applicator may include a resonator body and a plate. The resonator body may be provided on the plate, in such a manner the plate may be between the generated plasma and the resonator body. In embodiments, the resonator body, the plate, or both the resonator body and the plate are formed from or coated with a dielectric material. In embodiments, the resonator body and the plate may be formed from the same dielectric material. In further embodiments, the plate and the resonator body may be formed as a single monolithic structure.

Microwave plasma applicators according to the present technology may have competing design requirements. For example, the resonator body may require a material composition (and dimensions) that provide for a desired mode of resonance. For example, a single mode resonance may be used in some instances. However, the plate benefits from a resistance to the plasma environment. Accordingly, a balance between plasma resistance and mode of resonance should be considered, in embodiments. This can lead to undesirable dimensions of the applicator (e.g., larger dimensions), as well as providing sub-optimal resistance to the plasma environment.

Therefore, embodiments disclosed herein may include a microwave applicator architecture with a resonator body that includes a first dielectric material and a plate that includes a second dielectric material that is different than the first dielectric material. That is, the resonator body may be a discrete component that sits on (or is otherwise coupled to) the plate. This allows for the design of the resonator body to be optimized for producing the desired mode of resonance with a desired form factor, while also enabling high resistance to the plasma environment. In embodiments, the modular construction of the microwave applicator allows for easy modification in order to accommodate different plasma chemistries. For example, the plate may be swapped for a different material plate when the plasma chemistry is changed. Additionally, the plate may be coated with a material that is resistant to a particular plasma chemistry. In embodiments, the microwave applicator may include a single plate and a single resonator body. However, embodiments are not limited to such configurations. For example, the microwave applicator may include a single plate with a plurality of resonator bodies arranged across the plate. Such embodiments may allow for additional microwave power to be coupled into the plasma, as an example.

Embodiments disclosed herein allow for the integration of remote plasma sources in various locations of the semiconductor processing tool. In one embodiment, the remote plasma source is provided upstream of the main processing chamber. For example, the remote plasma source may include an antechamber in which the plasma is generated, and excited gas flows out an exhaust of the remote plasma source into the main processing chamber. Additionally, embodiments may integrate a remote plasma source downstream of the main processing chamber. For example, a remote plasma source may be provided along the foreline. Such an embodiment may allow for improved cleaning of the foreline and exhaust system.

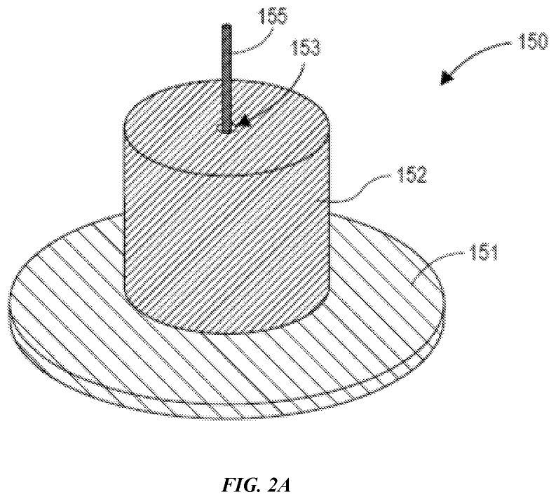

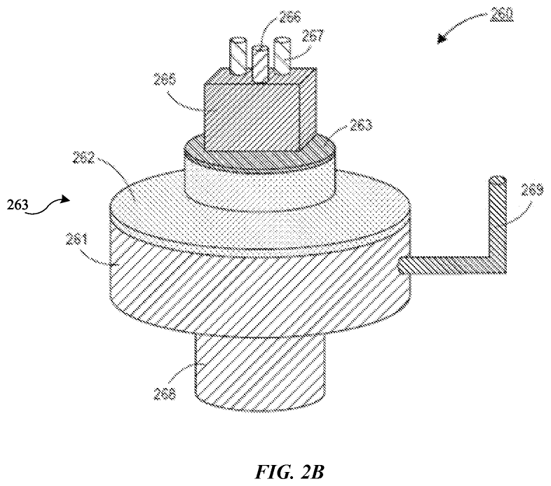

Nonetheless, referring now to FIG. 2A, a perspective view illustration of a microwave applicator 150 is shown, in accordance with an embodiment. In an embodiment, the microwave applicator 150 includes a plate 151 and a resonator body 152. The resonator body 152 may rest on (e.g. contact or be supported by) a top surface of the plate 151. The resonator body 152 may be removably coupled to the plate 151. That is, the plate 151 may be removed from the resonator body 152. This allows for changing out the plate 151 in order to accommodate different plasma chemistries, in embodiments, as well as for re-applying a coating after use. In embodiments, the resonator body 152 may include a hole 153. The hole 153 may be at an approximate axial center of the resonator body 152. The hole 153 may be sized to receive an electrically conductive pin 155. The pin 155 may be electrically coupled to a solid state microwave power source (not shown). As such, microwave power may be delivered to the resonator body 152.

In the illustrated embodiment, the resonator body 152 is cylindrical. Although, it should be appreciated that other shapes may be used for the resonator body 152 (e.g., prisms, quadrilaterals, elliptical shapes, etc.). Similarly, the plate 151 may be cylindrical. Other shapes may be used for the plate 151. For example, the plate may be a rectangular, prism, elliptical, or the like. In embodiments, a thickness of the plate 151 may be smaller than a diameter of the plate 151 (or a width or length of the plate 151). In embodiments, a thickness of the plate 151 may be approximately 10 mm or less, or approximately 5 mm or less. As used herein, “approximately” may refer to a range of values within ten percent of the stated value, or such as within five percent of the stated value. For example, approximately 10 mm may refer to a range from 9 mm to 11 mm.

In embodiments, the resonator body 152 may be formed from or coated with a first dielectric material and the plate 151 may be formed from a second dielectric material that is different than the first dielectric material. In embodiments, the first dielectric material may be or include Al, alumina (Al₂O₃), electroless nickel plated aluminum, AlO, MgF₂, YF₃, NiF₂, LiF, BaF₂, CaF₂ or a combination thereof. However, other dielectric materials may also be used for the first dielectric material of the resonator body 152. In some embodiments, the first dielectric material may be an aluminum containing material, a nickel containing material, or a combination thereof. Namely, the present technology has surprisingly found that the material forming the resonator body may impact the etch selectivity, etch rate, or combination thereof, of one or more target materials (e.g. materials targeted for etching during an etch operation, discussed in greater detail below). Without wishing to be bound by theory, it is believed that the increased dissociation achieved by the microwave plasma source discussed herein provides greater interaction with the microwave application. Thus, in embodiments, a first dielectric material may be selected based upon its interaction with the one or more plasma precursors. As an example only, nickel containing coatings or body materials may interact with halogen containing materials to increase etch selectivity and etch rate for silicon germanium materials (SiGe), particularly selectivity of SiGe over oxide and nitride containing materials. As a further example, a hydrogen rich environment may benefit from an aluminum containing coating or material in order to increase selectivity for oxides and nitrides, such as oxides and nitrides compare to SiGe, as an example only. However, it should be understood that various combinations of coatings or body materials, and process conditions may be contemplated herein, as will be discussed in greater detail below.

Nonetheless, in embodiments, the second dielectric material may be or include quartz, alumina, sapphire, MgF₂, yttrium aluminum garnet, Y₂O₃, MgO, calcium fluoride, barium fluoride, lithium fluoride, fused silica, borosilicate glass, or combinations thereof. In embodiments, the second dielectric material may be or include quartz, aluminum, sapphire, or combinations thereof. Furthermore, in embodiments, the second dielectric material may be or include coated or uncoated sapphire.

Referring now to FIG. 2B, a perspective view illustration of a remote plasma source 260 is shown, in accordance with embodiments of the present technology. In embodiments, the remote plasma source 260 may include a housing 264. The housing 264 may include a lower portion 261 and an upper portion 262. The lower portion 261 and the upper portion 262 may enclose a microwave applicator (not visible in FIG. 2B). The microwave applicator may be similar to or interchangeable with the microwave applicator described above with respect to FIG. 2A and may be utilized in one or more systems as discussed herein. For example, the microwave applicator may include a resonator body that is provided over a plate. The bottom of the plate may be exposed to a volume in which the remote plasma is formed. The interior construction of the remote plasma source 260 is described in greater detail below. In an embodiment, the lower portion 261 and the upper portion 262 of the housing may be an electrically conductive material. For example, the lower portion 261 and the upper portion 262 may comprise aluminum or the like. The lower portion 261 and the upper portion 262 may be electrically grounded in embodiments.

In embodiments, a spacer 263 may be provided over the upper portion 262 of the housing. The spacer 263 may be coupled to a matching unit 265. The matching unit 265 may enable impedance matching between the microwave power source (not shown) and the plasma load. The matching unit 265 may have any suitable configuration common to existing matching architectures. In an embodiment, the matching unit 265 may be or include a power input 266. The power input 266 may be configured to couple with a cable for transmitting the microwave power. The matching unit 265 may be actively cooled. For example, a fluid input 267 and a fluid output 267 may be provided on the matching unit 265. The input/output 267 may be fluidically coupled to a liquid cooling reservoir (not shown).

A gas input 269 may be coupled into the housing. The gas input 269 may provide one or more processing gasses into the chamber within the housing. For example, processing gasses such as, but not limited to, hydrogen containing gases, fluorine containing gasses, oxygen containing gasses, chlorine containing gasses, and the like may be provided along gas input 269. Inert gasses (e.g., nitrogen, argon, etc.) may also be provided through the gas input 269. In embodiments, the remote plasma source 260 may also include an exhaust 268. The exhaust 268 may be coupled to the lower portion 261 of the housing. The exhaust 268 may be coupled to the main processing chamber (e.g., a processing region which will be discussed in greater detail below). As such, excited gasses from the plasma generated in a chamber in the housing can flow into the main processing chamber.

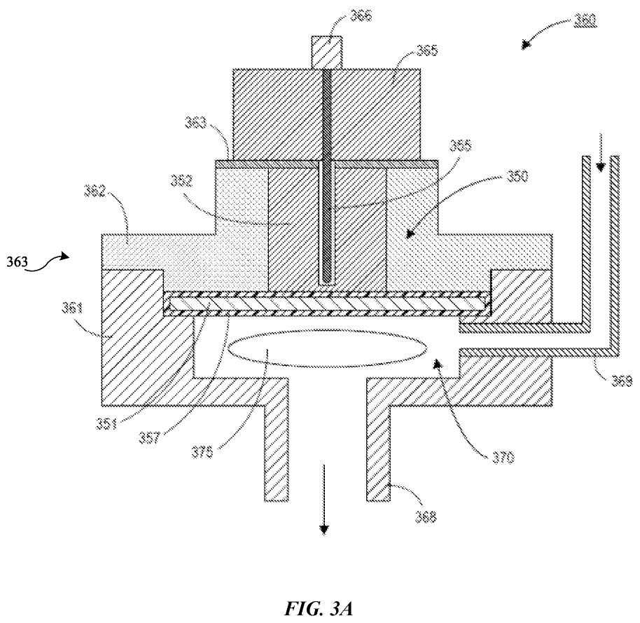

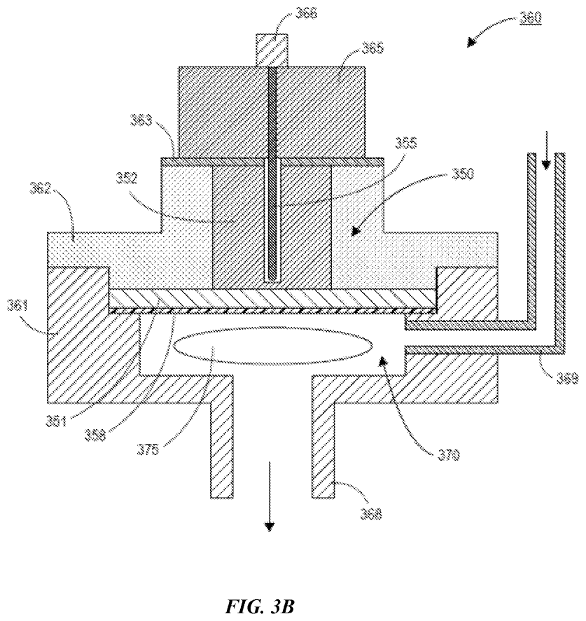

Referring now to FIGS. 3A and 3B, a series of cross-sectional illustrations depicting one or more remote plasma sources 360 according to the present technology is shown. The remote plasma sources 360 in FIGS. 3A and 3B may be similar to the remote plasma source 260 in FIGS. 1 and/or 2A and 2B, or may be different.

Referring now to FIG. 3A, a cross-sectional illustration of a remote plasma source 360 is shown, in accordance with embodiments of the present technology. FIG. 3A may include one or more components discussed above with regard to FIGS. 1, 2A, and/or 2B, and may illustrate further details relating to that chamber. As shown, the remote plasma source 360 may include a housing 364 with a lower portion 361 and an upper portion 362. The lower portion 361 of the housing 364 may define at least a portion of a remote plasma region 370. The plasma 375 may be generated in the remote plasma region 370. In embodiments where the remote plasma source 360 is provided upstream of the processing region (not shown), the remote plasma region 370 may be referred to as an antechamber. The remote plasma region 370 may be fluidically coupled to the main processing chamber and a processing region therein, through an exhaust 368 at the bottom of the remote plasma source 360. In an embodiment, the remote plasma region 370 may be fed gasses from gas input 369. While a single gas input 369 is shown, it is to be appreciated that multiple gas inputs 369 may be used in embodiments.

In embodiments, the microwave applicator 350 may be provided within the housing. For example, sidewalls of the resonator body 352 may be surrounded by the upper portion 362 of the housing. The plate 351 under the resonator body 352 may be contacted by both the lower portion 361 and the upper portion 362 of the housing. More particularly, the lower portion 361 may include a ledge on which the plate 351 is supported. The plate 351 may separate the resonator body 352 from the remote plasma region 370. The plate 351 may have a thickness that is less than or about 10 mm, such as less than or about 9 mm, such as less than or about 8 mm, such as less than or about 7 mm, such as less than or about 6 mm, such as less than or about 5 mm. In embodiments, the plate 351 may exhibit a diameter that is greater than a diameter of the remote plasma region 370. In embodiments, a diameter of the plate 351 may be less than or about 12 cm, such as less than or about 10 cm, such as less than or about 8 cm, such as less than or about 6 cm.

The resonator body 352 may include a pin 355 that extends through the hole in an approximate axial center of the resonator body 352. In embodiments, the axial center of the resonator body 352 is aligned with an axial center of the exhaust 368. The pin 355 may be coupled to the matching unit 365 and a connector 366. The matching unit 365 may be separated from the resonator body 352 by a spacer 363.

In embodiments, the resonator body 352 may include or be coated with a first dielectric material, and the plate 351 may include or be coated with a second dielectric material. As noted above, in embodiments, the first dielectric material may be different than the second dielectric material. That is, in embodiments, a material selection of the resonator body 352 may be decoupled from the material selection for the plate 351. For example, the plate 351 may be optimized to withstand a plasma environment within the remote plasma region 370 without significant erosion or other wear. Additionally, the plate 351 may be swapped out with a plate 351 with a different material if the plasma chemistry is changed.

For instance, in embodiments, plate 351 may be coated with a coating 357, such as a coating formed from or including the second dielectric material. In embodiments, the coating 357 may be provided around all exterior surfaces of the plate 351. A uniform coating 357 may be provided, in embodiments, but is not required. That is, a thickness of the coating 357 and the material composition of the coating 357 may be uniform across the plate 351. However, in embodiments, it may be desired to include a thicker coating on chamber facing surface of plate 351.

In embodiments, coating 357 may allow for even greater flexibility in the design of the microwave applicator 350. For example, the plate 351 may be formed from a material selected for improved mechanical properties. Thus, the coating 357 may then be used as a protective barrier for the plate 351. As such, the plate 351 may be protected from the plasma environment of the remote plasma region 370 without sacrificing improved mechanical properties. In embodiments, the coating 357 may have a thickness that is less than or about 1,000 μm, such as less than or about 900 μm, such as less than or about 800 μm, such as less than or about 700 μm, such as less than or about 600 μm, such as less than or about 500 μm, or such as greater than or about 200 μm, such as greater than or about 300 μm, such as greater than or about 400 μm. In such a manner, a robust coating may be provided.

The use of the coating 357 may allow for the plate 351 to be formed from the same material as the resonator body 352. For example, the plate 351 and the resonator body 352 may both include or be formed from alumina. In such embodiments, the coating 357 may be a different material than the plate 351 and the resonator body 352, such as any one or more of the materials discussed above in regard to the second dielectric material.

Referring now to FIG. 3B, a cross-sectional illustration of a remote plasma source 360 is shown, in accordance with embodiments of the present technology. Namely, FIG. 3B illustrates a plate 351 having a coating 358 that is provided over a single surface of the plate 351, as discussed above. More particularly, the coating 358 may be provided on a surface of the plate 351 that is exposed to the plasma environment in the remote plasma region 370 (e.g. a chamber facing surface). In embodiments, the coating 358 may span the entire bottom surface of the plate 351, or more than one surface, such as opposed bottom and top surfaces of plate 351, or more than two surfaces. Nonetheless, coating 358 may include or be formed from any one or more of the second dielectric materials discussed above, as well as any one or more of the thicknesses discussed in regards to coating 357.

Furthermore, in embodiments, the coating 358 may contact the lower portion 361 of the housing. More particularly, the coating 358 may contact a ledge of the lower portion 361 that is used to support the plate 351. In an embodiment, the top surface of the plate 351 may be in direct contact with the resonator body 352. The top surface of the plate 351 may also directly contact the upper portion 362 of the housing.

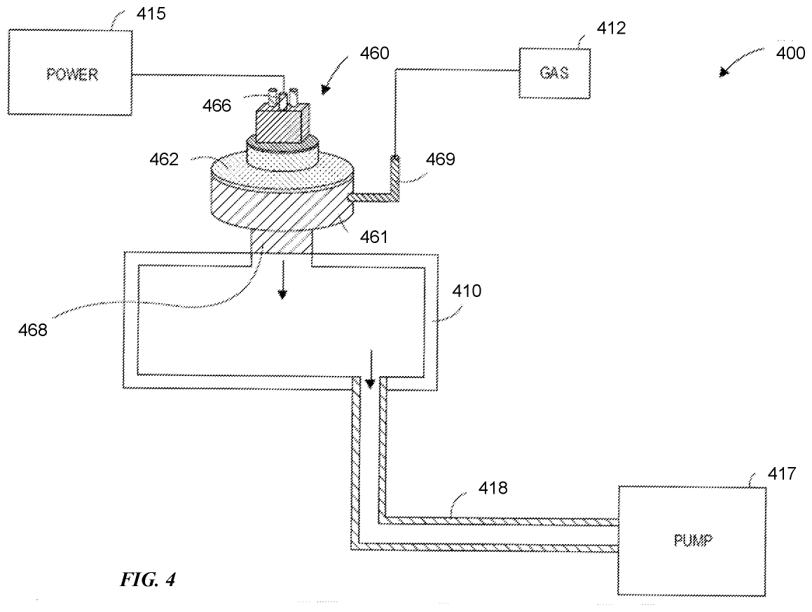

Referring next to FIG. 4, which illustrates a schematic drawing of a semiconductor processing tool 400, in accordance with embodiments of the present technology. In embodiments, the semiconductor processing tool 400 may include a processing region 410. For instance, in embodiments, a substrate, such as a wafer or the like, may be provided in the processing region 410 during processing. The processing region 410 may be a chamber suitable for maintaining sub-atmospheric pressures. For example, the processing region 410 may be considered a vacuum chamber. The semiconductor processing tool 400 may be a tool for material deposition, material removal (e.g., etching), treatment of various layers (e.g., plasma treatment), or any other semiconductor processing operation.

In embodiments, a remote plasma source 460 may be fluidically coupled to the processing region 410. For example, exhaust 468 may couple the remote plasma source 460 to the processing region 410. In embodiments, the remote plasma source 460 may include a housing with a lower portion 461 and an upper portion 462. Gas input 469 may fluidically couple a gas source 412 to a chamber within the remote plasma source 460. A power source 415, such as a solid state microwave power source 415, is coupled to a power input 466 of the remote plasma source 460.

In embodiments, the remote plasma source 460 may be or be similar to any of the remote plasma sources described herein. For example, the remote plasma source 460 may include a microwave applicator with a plate and a resonator body over the plate. In embodiments, the plate may be a different material than the resonator body, or may be coated in a different material as discussed above. In other embodiments, the plate may be lined with a coating. The plate separates the resonator body from a chamber where the plasma is formed. In embodiments, the chamber of the remote plasma source 460 may be referred to as an antechamber. In embodiments, the processing region 410 may be coupled to a pump 417 in order to provide sub-atmospheric pressures in the processing region 410. The pump 417 may be coupled to the main processing chamber through a foreline 418, as an example. While not shown, it should be clear that processing tool 400 may include more than one remote plasma sources 460.

Regardless of the orientation, the components of processing tool 400 may be configured to withstand the operating environment during etching or other processing operations. The components of processing tool 400 may be an anodized or oxidized material, including hard anodized aluminum, for example. Each component within processing tool 400 that may be contacted by plasma effluents or other corrosive materials may be treated or coated to protect against corrosion. Alternative materials may also be utilized to protect against corrosion from plasma effluents including fluorine or chlorine in embodiments. For example, one or more components within processing tool 400 may be ceramic or quartz in embodiments. As a particular example, one or more components of a gas distribution assembly (not shown), such as a spacer, pumping liner, faceplate, blocker, or any component that may be contacted by plasma or non-plasma precursors may be or include quartz or ceramic.

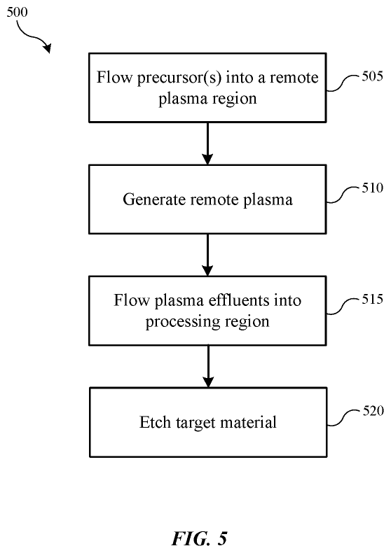

FIG. 5 shows exemplary operations in a method 500 according to some embodiments of the present technology. The method may be performed in a variety of processing chambers, including processing chamber 100 and/or 400 described above. Method 500 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated.

Method 500 may include additional operations prior to initiation of the listed operations. For example, additional processing operations may include forming structures on a semiconductor substrate, which may include both forming and removing material. Prior processing operations may be performed in the chamber in which method 500 may be performed, or processing may be performed in one or more other processing chambers prior to delivering the substrate into the semiconductor processing chamber in which method 500 may be performed. Regardless, method 500 may optionally include delivering a semiconductor substrate to a processing region of a semiconductor processing chamber, such as processing chamber 100 described above, or other chambers that may include components as described above. The substrate may be deposited on a substrate support/transfer platform, which may be a pedestal such as substrate support 104, and which may reside in a processing region of the chamber, such as processing region of processing chamber 120 described above.

Method 500 may or may not involve optional operations to develop the semiconductor structure to a particular fabrication operation. It is to be understood that method 500 may be performed on any number of semiconductor structures or substrates. The semiconductor substrate may be any number of materials, such as a base wafer or substrate made of silicon or silicon-containing materials, germanium, other substrate materials, as well as one or more materials that may be formed overlying the substrate during semiconductor processing.

In embodiments, the structure may be a semiconductor substrate, including bulk substrates, epitaxially grown substrates, and/or silicon on insulator wafer. As used herein, the term “semiconductor substrate” refers to a substrate in which the entirety of the substrate is comprised of a semiconductor material. The semiconductor substrate may include any suitable semiconducting material and/or combinations of semiconducting materials for forming a semiconductor structure. For example, the semiconducting layer may comprise one or more materials such as crystalline silicon (e.g., Si<100> or Si<111>), silicon oxide, strained silicon, silicon germanium, doped or undoped polysilicon, doped or undoped silicon wafers, patterned or non-patterned wafers, doped silicon, germanium, gallium arsenide, or other suitable semiconducting materials. In embodiments, the semiconductor material is silicon (Si). In one or more embodiments, the semiconductor substrate 300 includes a semiconductor material, e.g., silicon (Si), carbon (C), germanium (Ge), silicon germanium (SiGe), germanium tin (GeSn), other semiconductor materials, or any combination thereof. In one or more embodiments, the substrate 302 includes one or more of silicon (Si), germanium (Ge), gallium (Ga), arsenic (As), or phosphorus (P). Although a few examples of materials from which the substrate may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

In embodiments, the semiconductor material may be a doped material, such as n-doped silicon (n-Si), or p-doped silicon (p-Si). In embodiments, the substrate may be doped using any suitable process such as an ion implantation process. As used herein, the term “n-type” refers to semiconductors that are created by doping an intrinsic semiconductor with an electron donor element during manufacture. The term n-type comes from the negative charge of the electron. In n-type semiconductors, electrons are the majority carriers and holes are the minority carriers. As used herein, the term “p-type” refers to the positive charge of a well (or hole). As opposed to n-type semiconductors, p-type semiconductors have a larger hole concentration than electron concentration. In p-type semiconductors, holes are the majority carriers and electrons are the minority carriers.

Nonetheless, in embodiments, the semiconductor structure may have one or more materials formed over or within the semiconductor substrate (such as within a trench or isolation). In embodiments, such materials may include one or more semiconductor processing materials, such as one or more oxide materials, one or more nitride materials, a polysilicon material as discussed above, silicon germanium (SiGe), and combinations thereof. For instance, in embodiments, oxide materials may include silicon oxide, silicon oxycarbide, silicon oxynitride, silicon oxycarbonitride, other native oxides, combinations thereof, as well as other oxides as known in the art. Nonetheless, in embodiments, the oxide material may be silicon oxide. Nitride materials may include silicon nitride, boron nitride, gallium nitride, other native nitrides, combinations thereof, as well as other nitrides known in art. However, in embodiments, the nitride material may be silicon nitride. Furthermore, in embodiments, etch processes discussed herein may include an oxide bulk removal, a native oxide preclean, an oxide/nitride removal, a nitride recess, a silicon germanium recess, or a combination thereof.

Surprisingly, methods of the present technology provide selectivity of oxide containing materials to nitride containing materials of greater than or about 1:1, such as greater than or about 10:1, such as greater than or about 20:1, such as greater than or about 30:1, such as greater than or about 40:1, such as greater than or about 50:1, such as greater than or about 60:1, such as greater than or about 70:1, such as greater than or about 80:1, such as greater than or about 90:1, such as greater than or about 100:1, such as greater than or about 110:1, such as greater than or about 120:1, such as greater than or about 130:1, such as greater than or about 140:1, such as greater than or about 150:1, such as greater than or about 160:1, such as greater than or about 170:1, such as greater than or about 180:1, such as greater than or about 190:1, such as greater than or about 200:1, such as greater than or about 210:1, such as greater than or about 220:1, such as greater than or about 230:1, such as greater than or about 240:1, such as greater than or about 250:1, or any ranges or values therebetween.

Furthermore, methods of the present technology provide selectivity of oxide containing materials to SiGe containing materials of greater than or about 1:1, such as greater than or about 10:1, such as greater than or about 15:1, such as greater than or about 20:1, such as greater than or about 25:1, such as greater than or about 30:1, such as greater than or about 35:1, such as greater than or about 40:1, such as greater than or about 45:1, such as greater than or about 50:1, such as greater than or about 55:1, such as greater than or about 60:1, such as greater than or about 65:1, such as greater than or about 70:1, such as greater than or about 75:1, such as greater than or about 80:1, such as greater than or about 85:1, such as greater than or about 90:1, such as greater than or about 95:1, such as greater than or about 100:1, or any ranges or values therebetween.

Moreover, methods and systems according to the present technology also provide for high etch rates for oxide containing materials, alone or in combination with the high selectivity, such as greater than or about 20 Å/minute, such as greater than or about 25 Å/minute, such as greater than or about 30 Å/minute, such as greater than or about 35 Å/minute, such as greater than or about 40 Å/minute, such as greater than or about 45 Å/minute, such as greater than or about 50 Å/minute, such as greater than or about 55 Å/minute, such as greater than or about 60 Å/minute, such as greater than or about 65 Å/minute, such as greater than or about 70 Å/minute, such as greater than or about 75 Å/minute, such as greater than or about 80 Å/minute, such as greater than or about 85 Å/minute, such as greater than or about 90 Å/minute, such as greater than or about 95 Å/minute, such as greater than or about 100 Å/minute, such as greater than or about 110 Å/minute, such as greater than or about 120 Å/minute, such as greater than or about 130 Å/minute, such as greater than or about 140 Å/minute, such as greater than or about 150 Å/minute, such as greater than or about 160 Å/minute, such as greater than or about 170 Å/minute, such as greater than or about 180 Å/minute, such as greater than or about 190 Å/minute, such as greater than or about 200 Å/minute, such as greater than or about 210 Å/minute, such as greater than or about 220 Å/minute, such as greater than or about 230 Å/minute, such as greater than or about 240 Å/minute, such as greater than or about 250 Å/minute, or any ranges or values therebetween.

Surprisingly, methods of the present technology provide selectivity of SiGe containing materials to oxide and nitride containing materials of greater than or about 1:1, such as greater than or about 10:1, such as greater than or about 20:1, such as greater than or about 30:1, such as greater than or about 40:1, such as greater than or about 50:1, such as greater than or about 60:1, such as greater than or about 70:1, such as greater than or about 80:1, such as greater than or about 90:1, such as greater than or about 100:1, such as greater than or about 110:1, such as greater than or about 120:1, such as greater than or about 130:1, such as greater than or about 140:1, such as greater than or about 150:1, such as greater than or about 160:1, such as greater than or about 170:1, such as greater than or about 180:1, such as greater than or about 190:1, such as greater than or about 200:1, such as greater than or about 210:1, such as greater than or about 220:1, such as greater than or about 230:1, such as greater than or about 240:1, such as greater than or about 250:1, such as greater than or about 260:1, such as greater than or about 270:1, such as greater than or about 280:1, such as greater than or about 290:1, such as greater than or about 300:1, or any ranges or values therebetween.

Moreover, methods and systems according to the present technology also provide for high etch rates for SiGe containing materials, alone or in combination with the high selectivity, such as greater than or about 50 Å/minute, such as greater than or about 55 Å/minute, such as greater than or about 60 Å/minute, such as greater than or about 65 Å/minute, such as greater than or about 70 Å/minute, such as greater than or about 75 Å/minute, such as greater than or about 80 Å/minute, such as greater than or about 85 Å/minute, such as greater than or about 90 Å/minute, such as greater than or about 95 Å/minute, such as greater than or about 100 Å/minute, such as greater than or about 110 Å/minute, such as greater than or about 120 Å/minute, such as greater than or about 130 Å/minute, such as greater than or about 140 Å/minute, such as greater than or about 150 Å/minute, such as greater than or about 160 Å/minute, such as greater than or about 170 Å/minute, such as greater than or about 180 Å/minute, such as greater than or about 190 Å/minute, such as greater than or about 200 Å/minute, such as greater than or about 210 Å/minute, such as greater than or about 220 Å/minute, such as greater than or about 230 Å/minute, such as greater than or about 240 Å/minute, such as greater than or about 250 Å/minute, such as greater than or about 260 Å/minute, such as greater than or about 270 Å/minute, such as greater than or about 280 Å/minute, such as greater than or about 290 Å/minute, such as greater than or about 300 Å/minute, or any ranges or values therebetween.

Surprisingly, methods of the present technology provide selectivity of nitride containing materials to SiGe containing materials of greater than or about 1:1, such as greater than or about 10:1, such as greater than or about 20:1, such as greater than or about 30:1, such as greater than or about 40:1, such as greater than or about 50:1, such as greater than or about 60:1, such as greater than or about 70:1, such as greater than or about 80:1, such as greater than or about 90:1, such as greater than or about 100:1, such as greater than or about 110:1, such as greater than or about 120:1, such as greater than or about 130:1, such as greater than or about 140:1, such as greater than or about 150:1, such as greater than or about 160:1, such as greater than or about 170:1, such as greater than or about 180:1, such as greater than or about 190:1, such as greater than or about 200:1, such as greater than or about 210:1, such as greater than or about 220:1, such as greater than or about 230:1, such as greater than or about 240:1, such as greater than or about 250:1, or any ranges or values therebetween.

Furthermore, methods of the present technology provide selectivity of nitride containing materials to oxide containing materials of greater than or about 1:1, such as greater than or about 2:1, such as greater than or about 3:1, such as greater than or about 4:1, such as greater than or about 5:1, such as greater than or about 6:1, such as greater than or about 7:1, such as greater than or about 8:1, such as greater than or about 9:1, such as greater than or about 10:1, or any ranges or values therebetween.

Moreover, methods and systems according to the present technology also provide for high etch rates for nitride containing materials, alone or in combination with the high selectivity, such as greater than or about 10 Å/minute, such as greater than or about 15 Å/minute, such as greater than or about 20 Å/minute, such as greater than or about 25 Å/minute, such as greater than or about 30 Å/minute, such as greater than or about 35 Å/minute, such as greater than or about 40 Å/minute, such as greater than or about 45 Å/minute, such as greater than or about 50 Å/minute, such as greater than or about 55 Å/minute, such as greater than or about 60 Å/minute, such as greater than or about 65 Å/minute, such as greater than or about 70 Å/minute, such as greater than or about 75 Å/minute.

However, in embodiments, it may be desirable to remove a nitride containing material and an oxide containing material simultaneously. In such embodiments, the oxide and nitride may be removed at generally the same etch rate according to the ranges set forth above for the nitride containing materials. However, the present technology allows for the selective increase of etch speed of an oxide containing material to a nitride containing material, or to a nitride containing material to an oxide containing material. Thus, in embodiments, the oxide or nitride containing material may have an etch rate that is 5% or greater than an etch rate of the corresponding oxide or nitride, such as greater than or about 10%, such as greater than or about 15%, such as greater than or about 20%, such as greater than or about 25%, such as greater than or about 30%, or any ranges or values therebetween. Moreover, such tailoring of etch rates may be possible while maintaining the selectivity of the oxide or nitride containing material to SiGe.

Regardless of the substrate materials or target material, operation 505 of method 500 may include flowing one or more plasma precursors into a remote plasma region of a microwave remote plasma source. In embodiments, plasma precursors include one or more nitride containing halogen containing precursors, one or more hydrogen containing precursors, one or more nitrogen containing precursors, and combinations thereof, alone or in the presence of an inert carrier gas. Thus, in embodiments, the one or more plasma precursors may include NF₃, NH₃, H₂, Ar, He, NF₃/NH₃, NF₃/H₂, Cl₂, as well as combinations thereof. For instance, in embodiments, one or more of NF₃, NH₃, NF₃/NH₃, NF₃/H₂, and Cl₂ may be provided alone or in combination with H₂, Ar, He, or combinations thereof.

In embodiments, further increases in etch selectivity and/or etch rate may be achieved by controlling the plasma precursors. For instance, in embodiments, a ratio of hydrogen to a halogen containing precursor being flowed into the remote plasma region may also improve the selectivity of etch rates discussed above. For instance, in embodiments, a ratio of hydrogen to the fluorine-containing material is from about 0:1 to about 100:1, such as greater than or about 1:1, such as greater than or about 1.5:1, such as greater than or about 2:1:, such as greater than or about 3:1, such as greater than or about 4:1, such as greater than or about 5:1, such as greater than or about 6:1, such as greater than or about 7:1, such as greater than or about 8:1, such as greater than or about 9:1, such as greater than or about 10:1, or any ranges or values therebetween. In embodiments, a lower hydrogen to halogen ratio may improve the etch selectivity of SiGe to oxide and/or nitride containing materials, such as a ratio of less than 4:1, such as less than or about 3.5:1, such as less than or about 3:1, or any ranges or values therebetween. In embodiments, a higher hydrogen to halogen ratio may improve the etch selectivity of an oxide or nitride containing material to SiGe, such as greater than 3:1, such as greater than or about 4:1, such as greater than or about 5:1, such as greater than or about 6:1, or any ranges or values therebetween.

Nonetheless, in embodiments, when utilized, hydrogen may be flowed in to the remote plasma regions at rates of about 100 sccm to about 1600 sccm, such as greater than or about 150 sccm, such a greater than or about 200 sccm, such as greater than or about 250 sccm, such as greater than or about 300 sccm, such as greater than or about 350 sccm, such as greater than or about 400 sccm, such as greater than or about 450 sccm, such as greater than or about 500 sccm, such as greater than or about 550 sccm, such as greater than or about 600 sccm, such as greater than or about 650 sccm, such a greater than or about 700 sccm, such as greater than or about 750 sccm such as greater than or about 800 sccm, such as greater than or about 900 sccm, such as greater than or about 1000 sccm, such as greater than or about 1100 sccm, such as greater than or about 1200 sccm, such as greater than or about 1300 sccm, such as greater than or about 1400 sccm, such as greater than or about 1500 sccm, or any ranges or values therebetween.

In embodiments, when utilized, a halogen containing precursor, such as a fluorine or chlorine containing precursor, may be flowed in to the remote plasma regions at rates of about 10 sccm to about 150 sccm, such as greater than or about 15 sccm, such a greater than or about 20 sccm, such as greater than or about 25 sccm, such as greater than or about 30 sccm, such as greater than or about 35 sccm, such as greater than or about 40 sccm, such as greater than or about 45 sccm, such as greater than or about 50 sccm, such as greater than or about 55 sccm, such as greater than or about 60 sccm, such as greater than or about 65 sccm, such a greater than or about 70 sccm, such as greater than or about 75 sccm such as greater than or about 80 sccm, such as greater than or about 85 sccm, such as greater than or about 90 sccm, such as greater than or about 95 sccm, such as greater than or about 100 sccm, such as greater than or about 110 sccm, such as greater than or about 120 sccm, such as greater than or about 130 sccm, such as greater than or about 140 sccm, or any ranges or values therebetween.

Notwithstanding the orientation of the applicator or materials forming the applicator, the present technology has surprisingly found that a combination of a unique plasma and careful control of one or more process parameters, alone or in combination with the dielectric materials discussed above, may provide for the unexpected increase in etch selectivity and/or rate of a target material of a semiconductor substrate. For instance, as discussed above, it is believed that, due at least in part to the microwave applicator discussed herein, a unique plasma is provided according to methods of the present technology that exhibits a highly dissociated form which may have a high density, without exhibiting high ion energies. For instance, at operation 510, a remote plasma may be generated in the remote plasma region according to one or more of the following process conditions.

Thus, in embodiments, the microwave generated plasma may be generated at a frequency of about 300 MHz to about 100 GHz, such as greater than or about 400 MHz, such as greater than or about 500 MHz, such as greater than or about 600 MHz, such as greater than or about 700 MHz, such as greater than or about 800 MHz, such as greater than or about 900 MHZ, such as greater than or about 1000 MHz (e.g. 1 GHz), such as greater than or about 1.25 GHZ, such as greater than or about 1.5 GHz, such as greater than or about 1.75 GHz, such as greater than or about 2 GHz, such as greater than or about 2.25 GHz, such as greater than or about 2.5 GHz, such as greater than or about 2.75 GHz, such as greater than or about 3 GHZ, such as greater than or about 3.5 GHZ, such as greater than or about 4 GHz, such as greater than or about 4.5 GHZ, such as greater than or about 5 GHz, or such as less than or about 90 GHz, such as less than or about 80 GHZ, such as less than or about 80 GHZ, such as less than or about 70 GHZ, such as less than or about 60 GHz, such as less than or about 50 GHz, such as less than or about 40 GHz, such as less than or about 30 GHz, such as less than or about 20 GHz, such as less than or about 10 GHz, such as less than or about 8 GHz, such as less than or about 6 GHz, such as less than or about 5 GHz, such as less than or about 4 GHZ, such as less than or about 3 GHZ, such as less than or about 2.5 GHZ, or any ranges or values therebetween.

Moreover, in embodiments, plasmas formed utilizing microwave applicators discussed herein and according to the methods herein may exhibit a density of greater than or about 1×10¹⁰ per cm³, such as greater than or about 2×10¹⁰ per cm³, such as greater than or about 3×10¹⁰ per cm³, such as greater than or about 4×10¹⁰ per cm³, such as greater than or about 5×10¹⁰ per cm³, such as greater than or about 1×10¹¹ per cm³, such as greater than or about 5×10¹¹ per cm³, such as greater than or about 1×10¹² per cm³, such as greater than or about 5×10¹² per cm³, such as greater than or about 1×10¹³ per cm³, such as greater than or about ×10¹³ per cm³, or any ranges or values therebetween.

Furthermore, in embodiments, such densities may be achieved while also exhibiting low ion energy, such as less than or about 50 eV, such as less than or about 45 eV, such as less than or about 40 eV, such as less than or about 35 eV, such as less than or about 30 eV, such as less than or about 27.5 eV, such as less than or about 25 eV, such as less than or about 22.5 eV, such as less than or about 20 eV, such as less than or about 17.5 eV, such as less than or about 15 eV, such as less than or about 12.5 eV, such as less than or about 10 eV, such as less than or about 7.5 eV, such as less than or about 5 eV, or any ranges or values therebetween.

Plasmas according to the present technology may be generated at powers of greater than or about 10 watts, such as greater than or about 20 watts, such as greater than or about 25 watts, such as greater than or about 30 watts, such as greater than or about 35 watts, such as greater than or about 40 watts, such as greater than or about 45 watts, such as greater than or about 50 watts, or even greater than or about 60 watts, such as greater than or about 70 watts, such as greater than or about 80 watts, such as greater than or about 90 watts, such as greater than or about 100 watts, such as greater than or about 125 watts, such as greater than or about 150 watts, such as greater than or about 175 watts, such as greater than or about 200 watts, such as greater than or about 225 watts, such as greater than or about 250 watts, such as greater than or about 275 watts, such as greater than or about 300 watts, such as greater than or about 325 watts, such as greater than or about 350 watts, such as greater than or about 375 watts, such as greater than or about 400 watts, such as greater than or about 425 watts, such as greater than or about 450 watts, such as greater than or about 475 watts, such as greater than or about 500 watts, or such as less than or about 500 watts, such as less than or about 450 watts, such as less than or about 400 watts, such as less than or about 350 watts, such as less than or about 300 watts, or any ranges or values therebetween. Namely, the systems and methods discussed herein allow for a wide range of plasma power to be utilized while still maintaining targeted plasma properties discussed herein.

However, in embodiments, it may be beneficial to control plasma power to further tailor the selectivity and/or etch rate of a target material. For instance, in embodiments, a lower power, such as less than or about 70 watts, such as less than or about 60 watts, such as less than or about 50 watts, or any of the ranges or values discussed above, may further increase a selectivity of an oxide containing material as compared to SiGe, for example. Moreover, higher power, such as greater than or about 50 watts, such as greater than or about 60 watts, such as greater than or about 70 watts, such as greater than or about 80 watts, or any of the ranges or values discussed above may contribute to a co-etching of oxide and nitride, or an increase in SiGe etch rate relative to an oxide and/or nitride containing material.

In embodiments, the plasma may be generated at a pressure and/or the etching process may be maintained at a pressure of about 1 torr to about 10 torr, such as greater than or about 1.5 torr, such as greater than or about 2 torr, such as greater than or about 2.5 torr, such as greater than or about 3 torr, such as greater than or about 3.5 torr, such as greater than or about 4 torr, such as greater than or about 4.5 torr, such as greater than or about 5 torr, such as greater than or about 5.5 torr, such as greater than or about 6 torr, such as greater than or about 6.5 torr, such as greater than or about 7 torr, such as greater than or about 7.5 torr, such as greater than or about 8 torr, such as greater than or about 8.5 torr, such as greater than or about 9 torr, such as greater than or about 9.5 torr, or any ranges or values therebetween. Moreover, in embodiments, higher pressures may further improve the etching of oxide at a faster rate to nitride, such as pressures of greater than or about 4 torr, such as greater than or about 4.5 torr, such as greater than or about 5 torr, such as greater than or about 5.5 torr, such as greater than or about 6 torr, or any ranges or values discussed above. Furthermore, in embodiments, low pressures may further improve the co etching of a nitride and oxide material (e.g, etching both the oxide material and the nitride material together at a planned rate, such as 1:1 or within the percentages discussed above), such as less than or about 5 torr, such as less than or about 4.5 torr, such as less than or about 4 torr, such as less than or about 3.5 torr, such as less than or about 3 torr, or any of the values and ranges discussed above.

In embodiments, the plasma generation and/or the etching process may be conducted at relatively cold temperatures, for instance, as low as 20° C., up to about 125° C., such as greater than or about 25° C., such as greater than or about 30° C., such as greater than or about 35° C., such as greater than or about 40° C., such as greater than or about 50° C., such as greater than or about 60° C., such as greater than or about 70° C., such as greater than or about 80° C., such as greater than or about 90° C., such as greater than or about 100° C., such as greater than or about 110° C., such as greater than or about 120° C., or any ranges or values therebetween.

Nonetheless, at operation 515, the generated remote plasma effluents may be flowed from the remote plasma region to the processing region of a semiconductor processing system 100/400, as examples. In the processing region, the plasma effluents may contact the semiconductor substrate and the one or more target materials contained thereon or therein. Thus, the target material may be etched at one or more of the above discussed selectivities and/or etch rates discussed above.

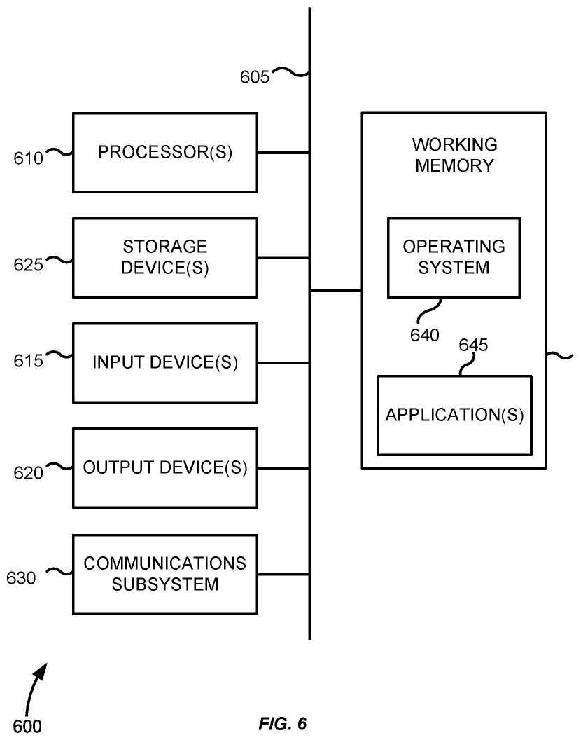

Nonetheless, as illustrated in FIG. 6, in embodiments, the systems and methods may be executed fully or in part by a processor which may be incorporated as part of the previously described controller or processor. For example, system 600 can represent some of the components of a controller described herein. FIG. 6 provides a schematic illustration of one embodiment of a system 600 that can perform the methods provided by various other embodiments, as described herein. FIG. 6 is meant only to provide a generalized illustration of various components, any or all of which may be utilized as appropriate. FIG. 6, therefore, broadly illustrates how individual system elements may be implemented in a relatively separated or relatively more integrated manner.

The system 600 is shown including hardware elements that can be electrically coupled via a bus 605 (or may otherwise be in communication, as appropriate), which may also be connected with a controller discussed above. The hardware elements may include a processing unit 610, including without limitation one or more processors, such as one or more central processing units (CPUs), graphical processing units (GPUs), special-purpose processors (such as digital signal processing chips, graphics acceleration processors, and/or the like); one or more input devices 615, which can include without limitation a keyboard, a touchscreen, receiver, a motion sensor, a camera, a smartcard reader, a contactless media reader, and/or the like; and one or more output devices 620, which can include without limitation a display device, a speaker, a printer, a writing module, and/or the like.

The system 600 may further include (and/or be in communication with) one or more non-transitory storage devices 625, which can comprise, without limitation, local and/or network accessible storage, and/or can include, without limitation, a disk drive, a drive array, an optical storage device, a solid-state storage device such as a random access memory (“RAM”) and/or a read-only memory (“ROM”), which can be programmable, flash-updateable and/or the like. Such storage devices may be configured to implement any appropriate data stores, including without limitation, various file systems, database structures, and/or the like.

The system 600 might also include a communication interface 630, which can include without limitation a modem, a network card (wireless or wired), an infrared communication device, a wireless communication device and/or chipset (such as a Bluetooth device, a 502.11 device, a Wi-Fi device, a WiMAX device, an NFC device, cellular communication facilities, etc.), and/or similar communication interfaces. The communication interface 630 may permit data to be exchanged with a network (such as the network described below, to name one example), other processors, and/or any other devices described herein. In many embodiments, the system 600 will further comprise a non-transitory working memory 635, which can include a RAM or ROM device, as described above.

The system 600 also can also include software elements, shown as being currently located within the working memory 635, including an operating system 640, device drivers, executable libraries, and/or other code, such as one or more application programs 645, which may include processor programs provided by various embodiments, and/or may be designed to implement methods, and/or configure systems, provided by other embodiments, as described herein. Merely by way of example, one or more procedures described with respect to the method(s) or systems discussed above might be implemented as code and/or instructions executable by a computer (and/or a processor within a computer); in an aspect, then, such special/specific purpose code and/or instructions can be used to configure and/or adapt a computing device to a special purpose computer that is configured to perform one or more operations in accordance with the described methods.

A set of these instructions and/or code might be stored on a computer-readable storage medium, such as the storage device(s) 625 described above. In some cases, the storage medium might be incorporated within a computer system, such as system 600. In other embodiments, the storage medium might be separate from a computer system (e.g., a removable medium, such as a compact disc), and/or provided in an installation package, such that the storage medium can be used to program, configure and/or adapt a special purpose computer with the instructions/code stored thereon. These instructions might take the form of executable code, which is executable by the system 600 and/or might take the form of source and/or installable code, which, upon compilation and/or installation on the system 600 (e.g., using any of a variety of available compilers, installation programs, compression/decompression utilities, etc.) then takes the form of executable code.

Substantial variations may be made in accordance with specific requirements. For example, customized hardware might also be used, and/or particular elements might be implemented in hardware, software (including portable software, such as applets, etc.), or both. Moreover, hardware and/or software components that provide certain functionality can comprise a dedicated system (having specialized components) or may be part of a more generic system. For example, a risk management engine configured to provide some or all of the features described herein relating to the risk profiling and/or distribution can comprise hardware and/or software that is specialized (e.g., an application-specific integrated circuit (ASIC), a software method, etc.) or generic (e.g., processing unit 610, applications 645, etc.) Further, connection to other computing devices such as network input/output devices may be employed.

Some embodiments may employ a controller, which may include a computer system, artificial intelligence, machine learning, combinations thereof, and the like (such as the system 600) to perform methods in accordance with the disclosure. For example, some or all of the procedures of the described methods may be performed by the system 600 in response to processing unit 610 executing one or more sequences of one or more instructions (which might be incorporated into the operating system 640 and/or other code, such as an application program 645) contained in the working memory 635. Such instructions may be read into the working memory 635 from another computer-readable medium, such as one or more of the storage device(s) 625. Merely by way of example, execution of the sequences of instructions contained in the working memory 635 might cause the processing unit 610 to perform one or more procedures of the methods described herein.

The terms “machine-readable medium” and “computer-readable medium,” as used herein, refer to any medium that participates in providing data that causes a machine to operate in a specific fashion. In an embodiment implemented using the system 600, various computer-readable media might be involved in providing instructions/code to processing unit 610 for execution and/or might be used to store and/or carry such instructions/code (e.g., as signals). In many implementations, a computer-readable medium is a physical and/or tangible storage medium. Such a medium may take many forms, including but not limited to, non-volatile media, volatile media, and transmission media. Non-volatile media include, for example, optical and/or magnetic disks, such as the storage device(s) 625. Volatile media include, without limitation, dynamic memory, such as the working memory 635. Transmission media include, without limitation, coaxial cables, copper wire, and fiber optics, including the wires that comprise the bus 605, as well as the various components of the communication interface 630 (and/or the media by which the communication interface 630 provides communication with other devices). Hence, transmission media can also take the form of waves (including without limitation radio, acoustic and/or light waves, such as those generated during radio-wave and infrared data communications).

Common forms of physical and/or tangible computer-readable media include, for example, a magnetic medium, optical medium, or any other physical medium with patterns of holes, a RAM, a PROM, EPROM, a FLASH-EPROM, any other memory chip or cartridge, a carrier wave as described hereinafter, or any other medium from which a computer can read instructions and/or code.

The communication interface 630 (and/or components thereof) generally will receive the signals, and the bus 605 then might carry the signals (and/or the data, instructions, etc. carried by the signals) to the working memory 635, from which the processor(s) 610 retrieves and executes the instructions. The instructions received by the working memory 635 may optionally be stored on a non-transitory storage device 625 either before or after execution by the processing unit 610 and controller.

In the embodiments described above, for the purposes of illustration, processes may have been described in a particular order. It should be appreciated that in alternate embodiments, the methods may be performed in a different order than that described. It should also be appreciated that the methods and/or system components described above may be performed by hardware and/or software components (including integrated circuits, processing units, and the like), or may be embodied in sequences of machine-readable, or computer-readable, instructions, which may be used to cause a machine, such as a general-purpose or special-purpose processor or logic circuits programmed with the instructions to perform the methods. These machine-readable instructions may be stored on one or more machine-readable mediums, such as CD-ROMs or other type of optical disks, floppy disks, ROMs, RAMs, EPROMs, EEPROMs, magnetic or optical cards, flash memory, or other types of machine-readable mediums suitable for storing electronic instructions. Alternatively, the methods may be performed by a combination of hardware and software.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein, the terms “about” or “approximately” or “substantially” may be interpreted as being within a range that would be expected by one having ordinary skill in the art in light of the specification.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

As used herein and in the appended claims, the singular forms “a”, “an”, and “the” include plural references unless the context clearly dictates otherwise. Thus, for example, reference to “an aperture” includes a plurality of such apertures, and reference to “the plate” includes reference to one or more plates and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A method of etching a target material of a semiconductor substrate, comprising:
flowing one or more plasma precursors through a microwave applicator into a remote plasma region of a semiconductor processing chamber;
generating a remote plasma within the remote plasma region at a microwave frequency, forming plasma effluents, wherein the generated remote plasma comprises a density of greater than 1×10¹⁰ per cm³, an ion energy of less than or about 50 eV, or a combination thereof;
flowing the plasma effluents into a processing region of the semiconductor processing chamber
the microwave applicator comprising
a resonator body, and
a plate, and
wherein the resonator body is formed from or coated with a first dielectric material and the plate is formed from or coated with a second dielectric material.

2. The method of claim 1, wherein the plasma effluents exhibit an etch selectivity between two or more of silicon germanium (SiGe), an oxide material, a nitride material, and a polysilicon material, of greater than or about 1:1.

3. The method of claim 2, wherein the etch selectivity is greater than or about 10:1.

4. The method of claim 2, wherein the etch selectivity is exhibited between SiGe and the oxide material, SiGe and the nitride material, or between SiGe and both the oxide material and the nitride material.

5. The method of claim 4, wherein the oxide material comprises silicon oxide, the nitride material comprises silicon nitride, or a combination thereof.

6. The method of claim 1, wherein the first dielectric material comprises Al, electroless nickel plated aluminum, AlO, MgF₂, YF₃, NiF₂, LiF, BaF₂, CaF₂ or a combination thereof.

7. The method of claim 1, wherein the second dielectric material comprises quartz, alumina, sapphire, MgF₂, yttrium aluminum garnet, Y₂O₃, MgO, calcium fluoride, barium fluoride, lithium fluoride, fused silica, borosilicate glass, or a combination thereof.

8. The method of claim 1, wherein the one or more plasma precursors comprise a hydrogen-containing precursor and/or a halogen-containing precursor, alone or in combination with an inert carrier gas.

9. The method of claim 8, wherein the one or more plasma precursors include hydrogen (H₂) and a fluorine-containing material, wherein a ratio of hydrogen to the fluorine-containing material is from about 0:1 to about 100:1.

10. The method of claim 9, wherein the ratio of hydrogen to the fluorine-containing material is greater than or about 3:1.

11. The method of claim 1, wherein a plasma source power is about 25 watts to about 300 watts.

12. The method of claim 11, wherein the plasma source power is less than or about 50 watts.

13. The method of claim 1, further comprising flowing hydrogen into the remote plasma region or the processing region at a rate of less than or about 1500 sccm.

14. The method of claim 1, wherein the etching is conducted at a pressure of about 1 torr to about 10 torr.

15. The method of claim 1, wherein the one or more plasma precursors comprise a nitrogen-containing precursor, wherein the nitrogen containing precursor is flowed into the processing region at a rate of about 25 sccm to about 150 sccm.

16. The method of claim 1, wherein the etch comprises an oxide bulk removal, a native oxide preclean, an oxide/nitride removal, a nitride recess, a silicon germanium recess, or a combination thereof.

17. The method of claim 1, wherein the etching is conducted at a temperature of about 20° C. to about 125° C.

18. A method of etching a target material of a semiconductor substrate, comprising:
flowing one or more plasma precursors through a microwave applicator into a remote plasma region of a semiconductor processing chamber;
generating a remote plasma within the remote plasma region at a microwave frequency, forming plasma effluents;
flowing the plasma effluents into a processing region of the semiconductor processing chamber
the microwave applicator comprising
a resonator body, and
a plate,
wherein
the resonator body is formed from or coated with a first dielectric material comprising Al, electroless nickel plated aluminum, AlO, MgF₂, YF₃, NiF₂, LiF, BaF₂, CaF₂ or a combination thereof, and
the plate is formed from or coated with a second dielectric material comprising quartz, alumina, sapphire, MgF₂, yttrium aluminum garnet, Y₂O₃, MgO, calcium fluoride, barium fluoride, lithium fluoride, fused silica, borosilicate glass, or a combination thereof.

19. The method of claim 18, wherein the second dielectric material is sapphire.

20. A method of etching a target material of a semiconductor substrate, comprising:
flowing one or more plasma precursors through a microwave applicator into a remote plasma region of a semiconductor processing chamber;
generating a remote plasma within the remote plasma region at a microwave frequency, forming plasma effluents;
flowing the plasma effluents into a processing region of the semiconductor processing chamber,
the microwave applicator comprising
a resonator body, and
a plate,
wherein the resonator body is formed from or coated with a first dielectric material and the plate is formed from or coated with a second dielectric material; and
wherein
the plasma effluents exhibit an etch selectivity between the target material and a second material that includes silicon germanium (SiGe), an oxide material, a nitride material, and a polysilicon material, wherein the second material is different than the target material,
the target material comprises the oxide material, and the first dielectric material comprises an aluminum containing material, a ratio of hydrogen to a fluorine-containing precursor material is greater than or about 3:1, a plasma source power is less than or about 50 watts, or a combination thereof, and/or
the target material comprises silicon germanium, and the ratio of hydrogen to a fluorine-containing precursor material is less than or about 3:1, the plasma source power is less than or about 50 watts, or a combination thereof.
